(19) United States
(12) Patent Application Publication
(10) Pub. No.: US 2008/0210939 A1
(43) Pub. Date: Sep. 4, 2008

(54) Method for Fabricating an Image Sensor Device with Reduced Pixel Cross-Talk

(76) Inventors: Jean-Baptiste Chevrier, Saint Vincent de Mercuze (FR); Olivier Salasca, Bernin (FR); Emmanuel Turlot, Corenc (FR)

Correspondence Address: BIRCH STEWART KOLASCH & BIRCH, PO BOX 747, FALLS CHURCH, VA, 22040-0747, US

(21) Appl. No.: 11/883,853

(22) PCT Filed: Feb. 22, 2006
(86) PCT No.: PCT/CH2006/000112

§ 371 Date: Aug. 7, 2007

Related U.S. Application Data
(60) Provisional application No. 60/657,128, filed on Feb. 28, 2005.

(51) Int. Cl. H01L 31/0376; H01L 31/18

(52) U.S. Cl. 257/54; 438/92; 257/292; 257/E31.048

(57) ABSTRACT

A method of fabricating an image sensor device (5) transferring an intensity of radiation (1) into an electrical current (i-i, ^{a}2) depending on said intensity, comprising the following steps in a vacuum deposition device: Depositing onto a dielectric, insulating surface a matrix of electrically conducting pads (7a, 7b) as rear electrical contacts, plasma assisted exposing said surface with pads to a donor delivering gas without adding a silicon containing gas, depositing a layer (15) of intrinsic silicon from a silicon delivering gas depositing a doped layer (17) and arranging an electrically conductive layer (19) transparent for said radiation (1) as a front contact. The method of fabricating an image-sensor-device and the image-sensor-device are avoiding disadvantages of the prior art. This means the image-sensor-device of the invention has a good ohmic contact, a low dark-current, no pixel-cross-talk and a reproducible fabrication-process.

### FIELD OF THE INVENTION

This invention relates to a method of fabricating an image sensor device and this device which converts an illuminating intensity of radiation into an electrical current depending on said intensity.

### BACKGROUND OF THE INVENTION

Image sensors comprising a circuitry of an integrated-semiconductor-circuit-structure are used in applications such as digital still camera, cellular-phone, video-camera, mice-sensor and so on.

Two main technologies are today competing: CCD (charge coupled device) and CMOS (complementary metal oxide semiconductor) image-sensors. In both technologies, the sensor is composed of arrays of pixels. Pixels are disposed in rows and columns. Each pixel contains a light-sensing-device that converts the light into electrical charges. In CMOS-technology a CMOS-circuitry is integrated next to a photodiode. The integrated circuitry allows an individual readout of the pixel. Whereas in CCD-technology the charges are transferred line by line and pixel to pixel to a common reading amplifier.

Recent market developments have created the need for high number of pixels and low cost image-sensors. CMOS-image-sensor-technology has lower cost partially because it takes the advantage of CMOS-mass-production. Moreover CMOS has the advantage that following the CMOS-process-technology-evolutions more and more complex functions can be added to each pixel. This allows a decrease of noise and an increase of sensitivity leading to the integration of more pixels on the same surface-area and for equivalent performances.

However, conventional CMOS-imaging-technology has limitations. Indeed, the light sensor next to the circuitry is usually a pn-junction implanted into a silicon-substrate. Due to the increasing number of metal-levels required for the CMOS-circuitry stacked on the surface of the substrate, the junction is located at the bottom of a deep-well. To avoid light-color-cross-talk, a light-beam has to be focused parallel to the well-walls in order to reach the corresponding sensor. Expensive and complex optical features such as micro-lenses have been recently developed.

One way to overcome this problem is to deposit a thin photodiode above the CMOS-circuitry. Using this technology the color-cross-talk-problem has to be resolved and further the photodiode occupies 100% of the sensor-surface area (100% fill-factor) leading to enhanced sensitivity thus allowing even further reduction in pixel-size. Such devices are described in the U.S. Pat. No. 6,501,065 B1; the U.S. Pat. No. 6,791,130 B2 and the WO 02/50921.

One of the main difficulties in such a device is to have an as good as possible electrical isolation between adjacent pixels. A poor isolation may lead to a so called pixel-cross-talk.

To overcome this problem the U.S. Pat. No. 6,501,065 B1 teaches that the bottom n-doped layer might be patterned and etched after deposition and before the deposition of the intrinsic-layer. The drawback is a non controllable interface between the n-doped layer and the intrinsic-layer. Indeed, after the deposition of the n-doped layer, the substrate of the integrated semiconductor-circuit-structure has to be removed out of the deposition-system into normal atmosphere, then a resist has to be spanned and patterned, then the n-doped layer must be dry- or wet-etched and finally the resist must be stripped. All these process-steps lead to uncontrolled surface of the layer prior to intrinsic layer-deposition. This uncontrolled interface might lead to lower diode-sensitivity and higher dark-current.

In U.S. Pat. No. 6,791,130 B2 two structures are described. Looking to one example, the stack of the U.S. Pat. No. 6,791,130 has a reversed structure by comparison to the structure of U.S. Pat. No. 6,501,065, because the bottom-layer is of a p-type. Indeed, a p-type layer is naturally poorly doped in a-Si:H. The drawback is that p-type atoms such as boron is known to diffuse into the intrinsic-layer while the latest is being deposited leading to a poor p-i junction and to poor diode-properties. Moreover, the light-absorption has to be minimized in the top doped layer, where the electrical field is weak in the doped region and hence the carrier-recombination is high. Thus having the n-doped layer at the top will require incorporating atoms such as carbon to minimize the light-absorption. This might lead to a higher dark-current (=electron injection) and a poor ohmic contact.

The other structure of the U.S. Pat. No. 6,791,130 B2 has a n-doped layer at the bottom, which is intentionally deteriorated by adding carbon into the layer. The drawback is that the n-doped layer acts as a poor ohmic contact which deteriorates the carriers (=electrons) collection. Moreover, it might also act as a poor barrier for minority carriers (=holes) when the diode is reverse biased, leading to a high dark-current (=high noise when the diode is not lighted).

In EP 1 344 259 a different photodiode-stack is proposed. Instead of a p-i-n or n-i-p junction a schottky-i-p-structure is proposed. A metal having the right Fermi-level to form a schottky-barrier with a-Si:H must be chosen (such as chromium). The drawback is, that the Schottky-barrier performances are very dependant on the metal/semiconductor-interface-state. By definition the surface of the metal after patterning and prior to an intrinsic layer deposition will not be well controlled and reproducible.

### PRESENTATION OF THE INVENTION

### Object of the Invention

It is an object of the invention to present a method of fabricating an image-sensor-device and an image-sensor-device which avoids the disadvantages of the prior art. This means an image-sensor-device having a good ohmic contact, a low dark-current, no pixel-cross-talk and a reproducible fabrication-process.

The object is achieved in that for fabricating an image-sensor-device in a vacuum deposition the following steps are comprised:

A matrix of electrically conducting pads is deposited onto a surface of a dielectric, insulating surface as rear electrical contacts. Then a plasma assisted exposing said surface with pads to a donor delivering gas without adding a silicon containing gas is done. A layer of intrinsic silicon is deposited by a silicon delivering gas. Then a p-doped layer is deposited and a transparent, electrically conducting layer is arranged as a front-contact.

The plasma assisted exposing deposits an ultra thin doped region. The thickness of the thin region and the matrix dimensions, this means the distances between the pads, are chosen in a manner that an ohmic contact between the pads and a below described photo-active-thin-film-structure is given, but no electrical conduction between the pads is generated. For getting this result, the distance between two adjacent pixels (typically several microns) has to be considered which is very large as compared to the thickness (typically 1 nm to 10 nm) of this ultra thin doped region. The doping atoms at the interface will improve the “vertical” ohmic contact whereas the lateral resistance at the interface will almost not be affected.

The ultra thin doped region, the layer of intrinsic silicon and the doped layer are forming a photo-active-thin-film-structure where each pad is one electrode and the transparent, electrical cover is a protection and the other electrode. This photo-active-thin-film-structure is an independent array of photo-detectors. But preferentially this photo-active-thin-film-structure could act together with a semiconductor structure which could be e.g. an amplifier, as described at the beginning in a CMOS-semiconductor-structure.

The inventive method is not limited only for CMOS-photodiodes; other semiconductor constructions are also possible. Also the plasma assisted exposing a surface to a donor delivering gas without adding a silicon containing gas is not only usable for producing an ultra thin doped region.

The plasma exposed, donor delivering gas is delivering an element or at least a compound with an element of the group V of the chemical periodical system as donor. The group V of the chemical periodical system contains the elements nitrogen, phosphorus, arsenic, antimony and bismuth. Typically, the two first elements are used. Good results were obtained with not diluted gases like PH₃ or diluted in a gas as argon (Ar) or hydrogen (H₂). Further, pure or diluted NH₃ can be used. The time of an n-plasma-treatment lasts between 1 to 10 minutes, preferably. The used radio-frequency power (rf-power) is in the same range as the one to deposit the layers of the photo-active-thin-film-structure.

Preferably the photoactive thin-film-layer-structure is deposited with a PECVD (plasma-enhanced chemical vapour deposition) technique and the transparent electrically conductive layer with a PVD (physical vapor deposition) technique. Especially the layer of intrinsic silicon and the doped, preferentially p-doped, layer are deposited with PECVD-technique and the transparent conducting layer with PVD-technique. Depositing is done without exposing the image-sensor to atmosphere in a cluster tool having PECVD- and PVD-reactors. Such a combined PECVD-/ PVD-reactoris e.g. the CLN 200 from Unaxis. The PECVD uses temperatures between 200° C. and 400° C.

Such a combined equipment has a so-called cluster-configuration, where in a vacuum-tight container around a central handling-manipulator different workstations are arranged. Normally one or two load-locks as sluices to the surrounding atmosphere do exist for providing wafers. Preferably, the image-sensor devices are produced on 8-inch wafers, but other dimensions are also possible. After evacuating the load-locks the manipulator grasps one of the wafers bringing it to a selected workstation. These work-stations are normally single-substrate-stations being adapted to a special application. An application could be CVD, PVD, a heating-station, a cooling-station, a measuring-station, a RTP (rapid thermal processing e.g. annealing) and so on. Program-controlled, the wafer passes the corresponding stations and after several processing-steps is positioned at a selected load-lock for releasing it into the surrounding atmosphere.

The following details description and all the patent claims give further advantageous embodiments and combinations of features of the invention.

### BRIEF DESCRIPTION OF THE INVENTION

The nature, objects, and advantages of the present invention will become more apparent to those skilled in the art after considering the following detailed description in connection with the accompanying drawings, wherein:

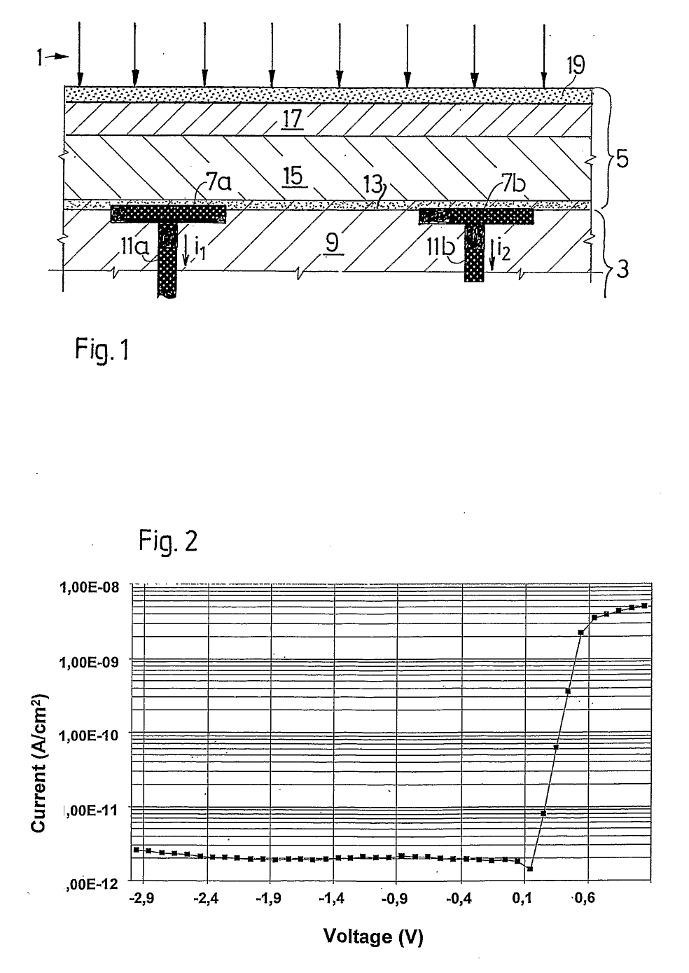

FIG. 1 shows a schematical cross-section through a proposed stack of a semiconductor-circuit of the invention and

FIG. 2 a current characteristic of a preferred embodiment of the invention.

### DETAILED DESCRIPTION OF PREFERRED EMBODIMENTS

In the following description of a preferred embodiment, reference is made to the accompanying drawings, which show by way of illustration a specific embodiment of the invention. It is to be understood by those of working skill in this technological filed that other embodiments may be utilized, and structural, as procedural changes may be made without departing from the scope of the present invention.

FIG. 1 shows an image-sensor for transferring an intensity of a radiation 1 into an electrical current i₁ and i₂ resp. depending on the intensity of an illuminating radiation 1. The image-sensor device is a semiconductor-structure made of a CMOS-semiconductor-structure 3 and a photoactive thin film-layer-structure 5. The photoactive thin film-layer-structure 5 is deposited onto the CMOS-semiconductor-structure 3. The CMOS-semi-conductor-structure 3 is terminated by electrically conducting pads disposed in a matrix where FIG. 1 shows only two pads 7a and 7b of said matrix arranged pads. The pads 7a and 7b are electrically isolated by a dielectrically isolating layer 9. The dielectric layer 9 is deposited over the CMOS-circuitry 3, where vias for rear electrodes 11a and 11b as the electrical contacts for the pads 7a and 7b have been eteched. The rear electrodes 11a and 11b and the pads 7a and 7b are for example from TiN, chromium or aluminum.

In a first processing step, an ultra thin doped region 13 is created. In this first step, the surface of the dielectric layer 9 which contains said pads 7a and 7b gets a plasma assisted exposing to a donor delivering gas without adding a silicon containing gas. The plasma is generated by a rf-frequency in a PECVD-reactor at a temperature between 150° C. and 350° C. The pressure in the reactor is between 0.1 mbar and 10 mbar. The donor delivering gas is delivering an element or at least one compound with an element of the group V of the chemical periodical system as a donor. Preferably phosphorus or nitrogen could be used where the used gas could be PH₃ (diluted in a gas stream of Ar or H₂ or without dilution). Good results were achieved using PH₃-gas diluted at 2% in H₂ with a processing-time of 10 sec to 10 min with a flow-rate between 10 sccm and 1000 sccm (standard centimeter cube per minute).

The thickness of the ultra thin doped region 13 and the matrix-dimensions, this means the distances between the pads, are chosen in a manner that an ohmic contact between the pads and a below described photo-active-thin-film-structure is given, but no electrical conduction between the pads is generated. A tentative physical and/or chemical explanation could be, that because the distance between two adjacent pads, which is typically several microns, is very large as compared to the doped region thickness being typically between 1 nm and 10 nm, the doping atoms at the interface will improve the “vertical” ohmic contact whereas the lateral resistance at the interface will almost not be affected.

In a second processing step onto the ultra thin doped region 13 an intrinsic layer 15 is deposited. In a third processing step onto the intrinsic layer 15 a doped, further layer 17 is deposited and in a fourth processing step an electrically conductive top layer 19, which is transparent for the illumination radiation is deposited. The photoactive thin-film-layer-structure with the region 13 and the layers 15, and 17 is produced by a PECVD-technique and the transparent electrically conductive layer 19 with a PVD-technique. For this processing preferably the above mentioned CLN 200 from Unaxis would be used, because producing the image-senor could be done without an exposition with the surrounding atmosphere.

In the second processing step for the intrinsic layer 15 amorphous silicon or microcrystalline silicon or polycrystalline silicon is used as a basis. The expression intrinsic means that the layer 15 is not doped. The PECVD-process is working with a SiH₄ gas-flow between 150° C. and 350° C. at a pressure between 0.1 mbar and 10 mbar in that manner that a layer-thickness between 100 nm and 1000 nm preferably between 200 nm and 1000 nm would be reached. This thickness is typically. A compromise between the quantum efficiency of the photoactive thin film-layer-structure 5, this means between a ratio of generated charge carriers over the incident photons (radiation), and the aging of the pads 7a and 7b leads to the right thickness. Too thin a layer 15 will affect the quantum efficiency of the photoactive thin film-layer-structure 5 whereas too thick a layer 15 will lead to faster aging of the photoactive thin film-layer-structure 5.

In the third processing step for the doped layer 17 the same basic gas-flow (SiH₄) as for the intrinsic layer 15 is used with the difference, only for doping a trimethylboron-gas-flow diluted at 2% at a flow-rate between 10 sccm and 500 sccm is added for getting a boron doping. The thickness of the layer 17 would be between 5 nm and 50 nm. In this third processing step CH₄ with a flow-rate between 10 sccm and 500 sccm could be added in addition to the trimethylboron-gas. The carbon from CH₄ might be added to the p-layer 17 in order to minimize the light absorption in this layer 17 where the electron-hole-recombination probability is high due to a weak electrical field in the p-layer 17. The typical thickness of the layer 17 is 5 nm to 50 nm, preferably 10 nm to 50 nm.

The deposition with a PECVD-technique of the intrinsic layer 15 and the doped layer 17 would be a great difference to the plasma assisted exposing for creating the region 13. Using the PECVD-technique a layer is deposited. For receiving a doped layer, a silicon containing gas is used together with a matched gas flow for doping. With the aid of plasma a deposition is received. The electrical energy, the gas-flow of the starting-gas and the processing-time determine the thickness of the layer. Per contra the above plasma assisted exposing without a gas for depositing a layer, this means without adding a silicon containing gas, is only working with a doping gas. A real layer as known in the art is not deposited.

In the fourth processing step for the transparent electrically conductive layer 19 a PVD-technique is used for depositing indium-tin-oxide with a thickness between 10 nm and 100 nm.

Depending on the context and exact specifications of the device and moreover depending on the used processing system, the physical properties of each of the layers described above may vary and therefore no concluding list of exact process parameters can be given here. A man skilled in the art can, without adding inventive efforts, determine which steps have to be taken, within the scope of the invention, to achieve the desired result.

During operation, the photoactive thin-film-layer-structure 5 is usually reverse biased. The electrodes are the pads 7a/b and the layer 19. The layer 19 could have optical filter properties. Therefore the layer 19 could be only transparent for selected spectral areas (colors). When the structure 5 is illuminated, the absorbed photons generate electron/hole-pairs. The created carriers drift along the electrical field towards the p-doped layer 17 and the n-doped region 13 (towards the p-layer for the holes and towards the n-region for the electrons). Then the carriers are collected on the electrodes. The intrinsic-layer 15 must have a low defect density in order to minimize the electron/hole-recombination and then maximize the electrical signal. In order to enhance the carrier collection on the electrodes, the layer 17 and the region 13 must lead to a good ohmic contact. When the structure 5 is not lighted by the radiation 1, the remaining dark current has two origins. One is due to thermal generation of carriers from low energy-states. The high quality intrinsic layer 15 is required as well as good and well controlled interfaces between the layer 17 and the region 13. The second is due to minority carries injection from the metal electrodes (pad 7a/b and layer 19) through the region 13 and the layer 17. The region 13 and the layer 17 allow efficient barrier to minority carriers. Further, normally one of the main difficulties in such a structure 5 is to have an as good as possible electrical isolation between adjacent pads. A poor isolation may lead to a so-called pixel-cross-talk. As described above the isolation between the pads of the invention is good.

An intermediate layer which is not mandatory could be arranged between the intrinsic and the doped layer 15 and 17. This not shown intermediate layer has a gradient of doping concentration from the intrinsic to the doped layer 15 to 17. The intermediate layer allows a better distribution of the electrical field within the structure 5 in order to improve the carrier collection generated by the radiation 1 in the blue spectral region.

Advantages of the invention are
a good ohmic contact, because the n-plasma treatment (region 13) shows efficient doping effect,
a low dark-current, because the n-plasma treatment shows efficient doping effect leading to an efficient potential barrier avoiding minority carriers injection,
no pixel-cross-talk, because the n-plasma treatment as opposite to a n-layer does not lead to any electrical short cut between two adjacent pads,
a reproducible processing technique thanks to n-plasma treatment, and thanks to the rear electrical contact being weakly dependent on parameters such as the surface state of the metal of the pads before PECVD processing,
a good control of the n/intrinsic interface, because the intrinsic layer 15 is deposited after the n-plasma treatment without removing the wafer from the reactor to the surrounding atmosphere,
that any metal can be used for back side contact (in contrast to the proposal in EP1344259).

The current characteristic of a preferred embodiment of the inventive photoactive thin-film-layer-structure 5 is shown in FIG. 2. A very low dark current of 2 pA/cm² in the reverse mode, clearly shows the efficiency of the n-plasma treatment (plasma assisted exposing to donor delivering gas without adding a silicon containing gas) to stop minority carrier injections. A sharp increase of the current in the forward mode shows a good ohmic contact.

1-19. (canceled)

20. A method of fabricating an image sensor device converting an intensity of radiation into an electrical current depending on said intensity, comprising the following steps in a vacuum deposition device:
Depositing onto a dielectrically, insulating surface a matrix of electrically conducting pads as rear electrical contacts,
plasma assisted exposing said surface with pads to a donor delivering gas without adding a silicon containing gas,
depositing a layer of intrinsic silicon from a silicon delivering gas
depositing a doped layer and
arranging an electrically conductive layer transparent for said radiation as a front contact.

21. Method according to claim 20, characterized in that by said plasma assisted exposing an ultra-thin doped region is created, where its thickness in relation to said matrix dimensions is chosen in a manner that an ohmic contact between the pads and a photo-active-thin-film structure is given, but no electrical conduction between the pads is generated, where said photo-active-thin-film structure consists of said ultra-thin doped region, said layer of intrinsic silicon and said doped layer.

22. Method according to claim 21 characterized in that the photoactive thin-film-layer structure is deposited with a PECVD (plasma-enhanced chemical vapour) technique and the transparent electrically conductive layer with a PVD (physical vapor deposition) technique.

23. Method according to claim 20, characterized in that the pads are terminating a CMOS-semiconductor structure, where said structure is covered by a dielectric layer.

24. Method according to claim 20, characterized in that the plasma exposing, donor delivering gas is delivering an element or at least one compound with an element of the group V of the chemical periodical system as donor.

25. Method according to claim 20, characterized in that the plasma is generated at RF frequency in a PECVD-reactor at a temperature between 150° C. and 350° C. at a pressure between 0.1 mbar and 10 mbar with a flow rate between 10 sccm and 1000 sccm of PH₃ gas diluted in H₂ at 2%, during a time from 10 sec to 10 min.

26. Method according to claim 20, characterized in that the layer of intrinsic silicon is deposited in a PECVD-reactor at a temperature between 150° C. and 350° C. with SiH₄ gas flow between 10 sccm and 500 sccm at a pressure between 0.1 mbar and 10 mbar.

27. Method according to claim 20, characterized in that the doped layer is deposited as a p-doped layer in a PECVD-reactor at a temperature between 150° C. and 350° C. with a SiH₄-flow-rate between 10 sccm and 500 sccm together with trimethylboron-gas (TMB-gas) diluted at 2% in H₂ at a flow-rate between 10 sccm and 500 sccm.

28. Method according to claim 20, characterized in that during deposition of the doped layer, especially for the p-doped layer, carbon is incorporated in the layer by means of adding CH₄ gas with a flow between 10 sccm and 500 sccm.

29. Method according to claim 20, characterized in that the ultra-thin region, the layer of intrinsic silicon, the doped, especially the p-doped, layer and the transparent conducting layer are deposited without exposing the image sensor at atmosphere in a cluster tool having PECVD-and PVD-reactors.

30. An image sensor device for converting an intensity of radiation into an electrical current depending on said intensity, comprising
a matrix of electrically conducting pads as rear electrical contacts, deposited on a surface of an electrically insulating, dielectric layer,
an ultra-thin conducting region on said surface of said dielectric, said pads containing layer, where said region being produced by plasma assisted exposing the surface to a donor delivering gas without adding a silicon containing gas,
an intrinsic silicon layer following said ultra-thin conducting region,
a doped layer and
an electrically conductive layer transparent for said radiation.

31. Image sensor device according to claim 30 characterized by a circuitry of an integrated CMOS-semiconductor circuit structure, said electrically insulated, dielectric layer covering at least parts of said circuit structure, said pads being electrically coupled to said circuit structure.

32. Image sensor device according to claim 31 characterized in that the transparent, electrically conductive layer being a top layer, where the ultra-thin doped conducting region, the intrinsic layer, the doped layer and the electrically conductive top layer being a photoactive thin-film-layer structure, said photoactive structure being electrically isolated by said dielectric layer from the CMOS-semiconductor structure, where the thickness of said ultra-thin region and the matrix-dimensions are chosen in a manner that an ohmic contact between the electrically conducting pads and the photo active thin-film-layer structure is given, but no electrical conduction between the pads is generated.

33. Image sensor device according to claim 30, characterized in that the doped layer is a p-doped layer and amorphous silicon or microcrystalline silicon or polycrystalline silicon is used as a basis for the intrinsic layer and said p-doped layer.

34. Image sensor device according to claim 33 characterized in that the intrinsic layer is essentially amorphous silicon with a thickness between 200 nm and 1000 nm.

35. Image sensor device according to claim 33 characterized in that the doped layer is essentially boron doped amorphous silicon with a thickness between 5 nm and 50 nm.

36. Image sensor device according to claim 33, characterized in that the doped layer is also doped with carbon.

37. Image sensor device according to claim 30, characterized in that the transparent electrically conductive layer being essentially of indium-tin-oxide (ITO) with a thickness between 10 nm and 100 nm.

38. Image sensor device according to claim 30, characterized by an intermediate layer arranged between the intrinsic layer and the doped layer as a p-doped layer with a gradient p-doping concentration-variation from i-layer to p-layer.
